(19) United States
(12) Patent Application Publication
(10) Pub. No.: US 2006/0183303 A1
(43) Pub. Date: Aug. 17, 2006

(54) Crystallized semiconductor device, method for producing same and crystallization apparatus

(76) Inventors: Tetsuya Inui, Nara-shi (JP); Hiroshi Tsunazawa, Soraku-gun (JP); Shinya Okazaki, Nara-shi (JP)

Correspondence Address: EDWARDS & ANGELL, LLP, P.O. BOX 55874, BOSTON, MA, 02205, US

(21) Appl. No.: 10/542,663

(22) PCT Filed: Jan. 19, 2004
(86) PCT No.: PCT/JP04/00389

§ 371 Date: Jul. 18, 2005

(30) Foreign Application Priority Data
Jan. 20, 2003 (JP) 2003-011552

(51) Int. Cl. H01L 21/84; C30B 11/00; H01L 21/20

(52) U.S. Cl. 438/487; 438/149; 117/206

(57) ABSTRACT

In a method of manufacturing a crystallized semiconductor device of the present invention, a thermal diffusion layer (1) having higher thermal conductivity than that of a substrate (4) is formed on a surface of a semiconductor layer (2), and then laser light is applied to the semiconductor layer (2) from above the thermal diffusion layer (1). As a result, it becomes possible to manufacture the crystallized semiconductor device in which a crystal is longer than that of a conventional arrangement. According to the present invention, it is possible to provide the crystallized semiconductor device having the semiconductor layer in which the size of the crystal grain is larger than that of the conventional arrangement.

### TECHNICAL FIELD

The present invention relates to a method of manufacturing a crystallized semiconductor device manufactured by utilizing laser light, and a crystallization apparatus for crystallizing a semiconductor layer.

### BACKGROUND ART

A thin film transistor, used in a display device to which liquid crystal, electro luminescence (EL), or the like is applied, uses an active layer made of amorphous silicon or polycrystalline silicon. Because the thin film transistor (crystallized semiconductor device) using the active layer made of the polycrystalline silicon has greater mobility of electron than that of the thin film transistor using the active layer made of the amorphous silicon, the former thin film transistor has many advantages as compared with the latter thin film transistor.

Specifically, for example, in the thin film transistor using the active layer made of the polycrystalline silicon, it is possible to form not only a switching element in a pixel portion but also a drive circuit and some peripheral circuits around the pixel portion, those circuits being formed on a single substrate. Therefore, it becomes unnecessary to separately mount a driver IC and a drive circuit substrate on the display device. As a result, it becomes possible to provide the display device at low price.

The following is another advantage. Because the size of the transistor can be miniaturized, it is possible to reduce the size of the switching element formed in the pixel portion. This allows realization of a high aperture ratio. As a result, it becomes possible to provide the display device with high luminance and high definition.

In order to manufacture the thin film transistor (crystallized semiconductor device) using the active layer made of polycrystalline silicon, it is necessary to carry out, for example, a separate process in which an amorphous silicon thin film is formed on a glass substrate by using a method such as CVD or the like, and then the amorphous silicone is changed into the polycrystalline silicone.

For example, in a method of changing the amorphous silicon into the polycrystalline silicon, an annealing is carried out at a high-temperature of 600° C. or higher. However, in the case of manufacturing the polycrystalline silicone by using the above method, an expensive glass substrate capable of withstanding the high temperature needs to be used as a substrate on which the amorphous silicon is stacked. This hinders price reduction of the display device. However, in recent years, a technology of crystallizing the amorphous silicon at a low temperature of 600° C. or less by using laser light has been generalized. Therefore, it is possible to provide at low price the display device in which a polycrystalline silicon transistor is formed on an inexpensive glass substrate.

One common technology of crystallization using the laser light is as follows: (i) a glass substrate on which an amorphous silicon thin film is formed is heated to a temperature of substantially 400° C., and (ii) the glass substrate is continuously irradiated with a liner laser light having a length of 200 mm to 400 mm and a width of 0.2 mm to 1.0 mm while scanning the glass substrate at a constant speed. According to this method, it is possible to form a polycrystalline silicon thin film whose average grain size is substantially the same as a thickness of the amorphous silicon thin film. Here, the amorphous silicon irradiated with the laser light is not entirely molten in all depths in a direction of the thickness, but molten while leaving a partial amorphous region which is not molten. This allows (i) crystal nuclei to be generated on an entire region which is irradiated with the laser, (ii) crystals to grow toward an outermost layer of the silicon thin film, and (iii) crystal grains in random directions to be formed.

However, in order to obtain the display device with further higher performance, it is necessary to increase the size of each of the crystal grains of the polycrystalline silicon, and to control a direction in which the crystals grow. Many researches and developments have been made to obtain a performance close to monocrystal silicon.

Specifically, for example, a technology for increasing the size of the crystal is disclosed in Patent Document 1 (published Japanese translations of PCT international publication for patent applications No. 505241/2000 (Tokuhyo 2000-505241, published on Apr. 25, 2000)).

Patent Document 1 discloses a technology called Super Lateral Growth. A method described in Patent Document 1 is as follows: (i) a silicon thin film is irradiated with a pulse laser having a fine width, and (ii) the silicon thin film is molten and solidified in all the depths in the direction of the thickness in the area where the light is irradiated, so that the silicon thin film is crystallized. Specifically, (i) the silicon thin film is irradiated with the pulse laser, (ii) the area where the light is irradiated is molten in all depths in the direction of the thickness, (iii) the crystal grains are so controlled as to grow in a lateral direction from the boundary between a molten portion and a non-molten portion, that is, in a direction horizontal to the glass substrate, so that needle-shaped crystals are obtained.

Super Lateral Growth has a feature of realizing a large crystal which is obtained by growths of needle-shaped crystals which have a uniform crystal orientation. Such a large crystal is obtained as follows: (i) a first needle-shaped crystal is formed by an irradiation of a first pulse laser, and then (ii) an irradiation of a second pulse laser is carried out to one part of the needle-shaped crystal, which part has been irradiated by the first pulse laser, so that a second and longer needle-shaped crystal grows from the first needle-shaped crystal. The step (ii) is carried out repeatedly, so that such a large crystal is obtained.

In the semiconductor device disclosed in Patent Document 1, a silicon dioxide film is usually provided on the glass substrate to prevent impurities from diffusing, and an amorphous silicon film is further provided on the silicon dioxide film.

A method of manufacturing the polycrystalline silicon is disclosed, for example, in Patent Document 2 (Japanese Laid-Open Patent Publication No. 68520/2000 (Tokukai 2000-68520, published on Mar. 3, 2000)) and Patent Document 3 (Japanese Laid-Open Patent Publication No. 296023/1994 (Tokukaihei 6-296023, published on Oct. 21, 1994)). These Patent Documents disclose an arrangement of improving a property of a film obtained by (i) forming on a substrate a film whose thermal conductivity is different from that of the substrate and (ii) further forming a semiconductor layer (amorphous silicon layer) on the film. That is, according to Patent Documents 2 and 3, the film having the thermal conductivity different from those of the substrate and the semiconductor layer is formed between the substrate and the semiconductor layer.

However, in Patent Documents 1, a growth length of the crystal grain is 1 μm to 2 μm at longest. Therefore, in order to obtain a large crystal grain which grows from the first crystal, it is necessary to repeatedly carry out the irradiation of the pulse laser. Especially, in the case in which the growth length of the crystal is about 1 μm, in order to allow the crystal to continuously grow, it is necessary to irradiate the second pulse laser onto the crystal which has grown in irradiation of the first pulse laser so that the first and second pulse laser overlap. This causes the second pulse laser to be irradiated onto the portion of the crystal which is 0.5 μm away from the portion onto which the first pulse laser is irradiated. However, in order to always ensure a distance of 0.5 μm, a high-precision feeding mechanism having a resolution of a feeding accuracy of about 0.1 μm is required. This causes an increase in device costs. In addition, because each feeding amount is small, a processing speed is slow.

Moreover, as disclosed in Patent Documents 2 and 3, in an arrangement in which a layer (thermal diffusion layer) having the thermal conductivity different from those of the substrate and the semiconductor layer is provided between the substrate and the semiconductor layer, the thermal diffusion layer has higher thermal diffusivity than that of the other layers, so that heat can easily be diffused in a direction of the substrate (in a direction perpendicular to the substrate) from the thermal diffusion layer having high temperature. On this account, the semiconductor layer quickly decreases in temperature, so that a growth of the crystal of the semiconductor layer is hindered.

The present invention was made in view of the above problems, and an object of the present invention is to provide (i) a method of manufacturing a crystallized semiconductor layer and (ii) a crystallization apparatus, which can increase the size of the crystal grain of the semiconductor layer.

### DISCLOSURE OF INVENTION

In order to solve the above problems, a method of manufacturing a crystallized semiconductor device of the present invention includes the steps of: (i) forming a semiconductor layer on a substrate; and (ii) irradiating the semiconductor layer with laser light so as to crystallize the semiconductor layer, and the method further includes the step of: forming a thermal diffusion layer on a surface of the semiconductor layer, the thermal diffusion layer having higher thermal conductivity than thermal conductivity of the substrate, and in the step (ii), the semiconductor layer is irradiated with the laser light from above the thermal diffusion layer.

According to the above arrangement, the thermal diffusion layer is formed on the surface of the semiconductor layer, and then the semiconductor layer is irradiated with the laser light from above the thermal diffusion layer. By providing the thermal diffusion layer on the surface of the semiconductor layer, it becomes possible to slow down a speed of decrease in temperature of the semiconductor layer which has been molten by the laser light, as compared to a conventional arrangement. Specifically, when the semiconductor layer is irradiated with the laser light, the thermal diffusion layer is also irradiated with the laser light.

Therefore, heat accumulated in the thermal diffusion layer flows to the adjacent semiconductor layer. Moreover, because the heat is given from the thermal diffusion layer to the semiconductor layer, a temperature distribution of the molten semiconductor layer can be uniformized, as compared to the conventional arrangement. Therefore, when the molten semiconductor layer is crystallized, it is possible to increase the length of the crystal as compared to the conventional arrangement. Moreover, it is possible to increase, more than before, the length of the crystal formed by one-time irradiation of the laser light. Therefore, it is possible to decrease a time required for crystallization.

Thus, it is possible to achieve property improvements in a device formed on the crystallized semiconductor device manufactured by this method, and also possible to manufacture the device at low costs.

Moreover, in order to solve the above problems, the crystallized semiconductor device of the present invention is characterized by being manufactured by the method of the present invention.

According to the above arrangement, the semiconductor layer is crystallized by the method. Therefore, it is possible to provide the crystallized semiconductor device having the semiconductor layer whose size of the crystal grain is lager as compared to the conventional arrangement.

In order to solve the above problems, the crystallization apparatus of the present invention includes a crystallization means for irradiating a semiconductor device with laser light so as to crystallize a semiconductor layer, the semiconductor device having a thermal diffusion layer on a surface of the semiconductor layer provided on a substrate, the thermal diffusion layer having higher thermal conductivity than thermal conductivity of the substrate, the crystallization means emitting the laser light having a wavelength of 550 nm or less.

According to the above arrangement, in a non-crystallized semiconductor device including the thermal diffusion layer formed on the surface of the semiconductor layer, the semiconductor layer is irradiated with the laser light having a wavelength of 550 nm or less from above the thermal diffusion layer.

Because the crystallization means irradiates the semiconductor layer with the laser light from above the thermal diffusion layer, it is possible to slow down the speed of decrease in temperature of the semiconductor layer molten by the laser light, as compared to the conventional arrangement. Specifically, a part of the laser light having passed through the thermal diffusion layer is accumulated as the heat in the thermal diffusion layer. Then, the accumulated heat is given to the semiconductor layer, so that it becomes possible to restrain a decrease in temperature of the semiconductor layer. In this way, the size of the crystal formed in the semiconductor layer can be increased as compared to the conventional arrangement.

Moreover, it is possible to provide the crystallization apparatus which can (i) reduce an absorption of the laser light in the thermal diffusion layer and (ii) absorb the laser light greatly in the semiconductor layer, by irradiating the semiconductor layer from above the thermal diffusion layer with the laser light having a wavelength of 550 nm or less. As a result, it becomes possible to increase the efficiency of crystallization of the crystallized semiconductor device, and also possible to reduce manufacturing costs by reducing of a manufacturing time.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a side view showing a schematic arrangement of a crystallized semiconductor device manufactured by a method of manufacturing the crystallized semiconductor device in accordance with one embodiment of the present invention.

FIG. 2 is a plan view showing a schematic arrangement of a crystallization apparatus in accordance with one embodiment of the present invention.

FIG. 3 is a front view showing a state of crystallization of a semiconductor layer in the crystallized semiconductor device.

FIG. 4 is a graph showing a temperature distribution of an amorphous silicon film of a conventional semiconductor device, the amorphous silicon film being in the process of crystallization after it (i) is irradiated with the laser light, (ii) is molten, and (iii) decreases in temperature.

FIG. 5 is a graph showing a change in the temperature distribution of an amorphous silicon film 14 in the conventional semiconductor device, when the amorphous silicon film 14 decreases in temperature.

FIG. 6 is a graph showing a temperature distribution of a region in the vicinity of a molten region, in the case in which a non-crystallized semiconductor device in accordance with the present embodiment is irradiated with the laser light.

FIG. 7 is a graph showing a change in a temperature distribution of a semiconductor layer 2 in an arrangement of the present embodiment, the semiconductor layer 2 decreasing in temperature.

FIG. 8 is a side view showing another schematic arrangement of the crystallized semiconductor device.

### BEST MODE FOR CARRYING OUT THE INVENTION

### The First Embodiment

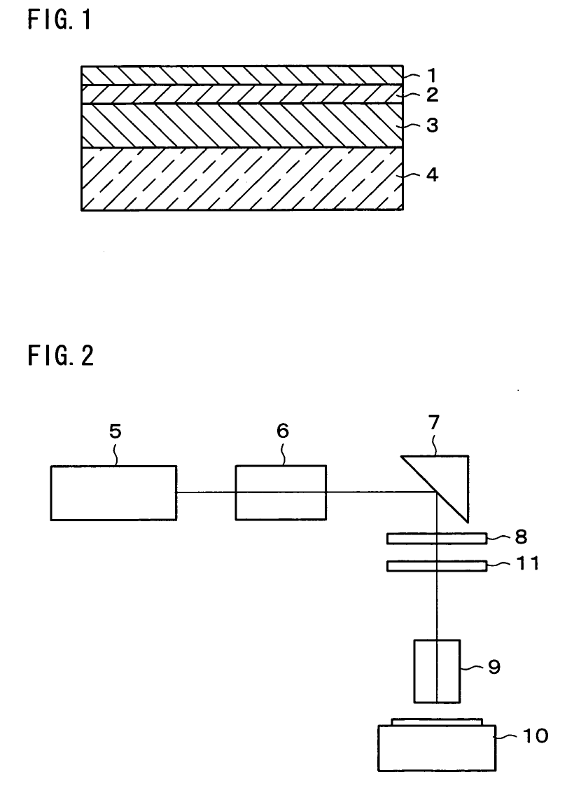

The following explains one embodiment of the present invention in reference to FIGS. 1 to 8.

A method of manufacturing a crystallized semiconductor device in accordance with the present embodiment includes the steps of (i) forming a semiconductor layer on a substrate and (ii) irradiating the semiconductor layer with laser light to crystallize the semiconductor layer. The method further includes the step of forming a thermal diffusion layer on a surface of the semiconductor layer, the thermal diffusion layer having higher thermal conductivity than that of the substrate, and in the step of crystallization (step (ii)), the irradiation of the laser light is carried out from above the thermal diffusion layer.

A non-crystallized semiconductor device in which the semiconductor layer is not crystallized is so arranged that a thermal diffusion layer having higher thermal conductivity than that of the substrate is formed on a surface of the semiconductor layer which is in an amorphous state or in a micro crystal state, and which is formed on the substrate.

FIG. 1 is a side view showing a schematic arrangement of a crystallized semiconductor device manufactured by the method of manufacturing the crystallized semiconductor device in accordance with the present embodiment. As shown in FIG. 1, the crystallized semiconductor device is so arranged that a diffusion preventing layer (low thermal conductivity layer) 3, a semiconductor layer 2, and a thermal diffusion layer 1 are stacked in this order on a glass substrate (substrate) 4. That is, the thermal diffusion layer 1 is formed on a surface of the semiconductor layer 2. In other words, when viewed from the semiconductor layer 2, the thermal diffusion layer 1 is formed on a side opposite to a side on which the substrate is provided. Moreover, a surface of the thermal diffusion layer 1 is exposed to the air, the surface being opposite to a surface in contact with the semiconductor layer 2.

The diffusion preventing layer 3 is provided for preventing impurities from diffusing from the glass substrate 4. As the diffusion preventing layer 3, a silicon dioxide film is used in the present embodiment, but the present invention is not limited to this. Any layer made of other materials can be used as long as the layer can prevent the impurities from diffusing from the glass substrate 4. In the case of using the silicon dioxide film as the diffusion preventing layer 3, the silicon dioxide film can be formed by, for example, Deposition, Sputter Deposition, CVD, or other method. The diffusion preventing layer 3 can have any thickness as long as the diffusion preventing layer 3 can prevent the impurities from diffusing from the glass substrate 4 to the semiconductor layer 2. Specifically, it is preferable that the thickness be in a range from 0.05 μm to 1 μm.

In the present embodiment, the semiconductor layer 2 is provided on the diffusion preventing layer 3. Amorphous silicon is usually used as the semiconductor layer 2. A film-forming method (layer-forming method) of forming the semiconductor layer 2 is CVD, Sputtering, Deposition, or other method. A thickness of the semiconductor layer 2 may be determined suitably according to a required property of a transistor, a process condition, etc. It is more preferable that a film thickness (layer thickness) be in a range from several tens of nanometers to several hundreds of nanometers, and it is especially preferable that the film thickness be in a range from 30 nm to 100 nm.

The semiconductor layer 2 just formed is normally amorphous and is not crystallized. Aggregate of very small crystals (micro crystals) may be obtained by some methods of forming a film. However, it is anyway difficult to obtain a large crystal grain. Therefore, if a transistor is formed directly on the semiconductor layer 2 just formed, the mobility of electron in the transistor becomes low. In view of the circumstances, in a semiconductor device to be ultimately obtained, the amorphous semiconductor layer 2 is subjected to crystallization. That is, the semiconductor layer 2 of the present embodiment has been crystallized. Note that a method of crystallization will be described later.

In the present embodiment, the thermal diffusion layer 1 is provided on the semiconductor layer 2. Specifically, the thermal diffusion layer 1 is provided on the surface of the semiconductor layer 2. The thermal diffusion layer 2 is made of a material having higher thermal conductivity than that of the glass substrate 4. Moreover, it is more preferable that the thermal diffusion layer 1 be made of a material having higher thermal conductivity than that of the diffusion preventing layer 3.

Further, it is desirable that the thermal diffusion layer 1 have high transmittance with respect to the laser light which irradiates the thermal diffusion layer 1 during Laser Annealing Treatment (in the step of crystallization) described later. Specifically, it is more preferable that the transmittance with respect to the laser light be 70% or higher. In the case in which the transmittance is lower than 70%, it becomes difficult for the laser light to reach the semiconductor layer 2. As a result, the crystallization of the semiconductor layer 2 may become inefficient.

It is more preferable that the thermal diffusion layer 1 have lower light absorptivity with respect to the laser light than that of the semiconductor layer 2. That is, it is more preferable that the thermal diffusion layer 1 have lower light absorptivity with respect to the laser light, which irradiates the semiconductor layer 2 to crystallize the semiconductor layer 2, than that of the semiconductor layer 2. In the case in which the thermal diffusion layer 1 has higher light absorptivity with respect to the laser light than that of the semiconductor layer 2, the laser light is not absorbed efficiently by the semiconductor layer 2. This may cause the crystallization to be inefficient.

It is preferable that the thermal diffusion layer 1 be made of chemical compound such as nitride or oxide of silicon or aluminum. More specifically, such chemical compound is exemplified by silicon nitride, aluminum nitride, aluminum oxide, etc. In the case in which the thickness of the semiconductor layer 2 is expressed as 100%, it is more preferable that the thickness of the thermal diffusion layer 1 be in a range from 50% to 400%. Specifically, it is preferable that the thickness be in a range from 5 nm to 200 nm. In the case in which the thickness of the thermal diffusion layer 1 is thinner than 50% of the thickness of the semiconductor layer 2, effect of thermal diffusion becomes small. This may cause no effect of accelerating the growth of the crystal of the semiconductor layer 2 during crystallization described later. On the other hand, in the case in which the thickness of the thermal diffusion layer 1 is more than 400% of the thickness of the semiconductor layer 2, energy becomes necessary for heating up the thermal diffusion layer 1 itself. This may cause a necessity of extra energy of the laser light.

The following explains a method of manufacturing the semiconductor device.

A method of manufacturing the semiconductor device of the present embodiment includes the steps of (i) forming the semiconductor layer 2 on the glass substrate 4, (ii) providing the thermal diffusion layer 2 on the surface of the semiconductor layer 2, the thermal diffusion layer 2 having higher thermal conductivity than that of the glass substrate 4, and (iii) irradiating the semiconductor layer 2 with the laser light from above the thermal diffusion layer 1 so that the semiconductor layer 2 is crystallized.

In the step of forming the semiconductor layer, the semiconductor layer 2 is formed on the substrate 4. Specifically, in the present embodiment, the diffusion preventing layer 3 is formed on the glass substrate 4 in advance, and then the semiconductor layer 2 is formed on the diffusion preventing layer 3. That is, the diffusion preventing layer 3 and the semiconductor layer 2 are stacked in this order on the glass substrate 4. A method of forming the semiconductor layer 2 on the diffusion preventing layer 3 is well-known. As such, a detailed explanation is omitted.

In the step of forming the thermal diffusion layer, the thermal diffusion layer 1 is formed on the surface of the semiconductor layer 2. Specifically, the thermal diffusion layer 1 may be formed by Sputtering, Vacuum Deposition, Thermal CVD, Plasma CVD, or other method. Note that another method of forming a thin film may be selected according to a material of the thermal diffusion layer 1. Note also that the thermal diffusion layer 1 of the present embodiment may be formed on the surface of the semiconductor layer 2 by using a method similar to a method which is used in a conventional semiconductor device when providing the thermal diffusion layer between the semiconductor layer and the substrate.

After the thermal diffusion layer 1 is formed on the surface of the semiconductor layer 2, the laser light irradiates the semiconductor layer 2 from above the thermal diffusion layer 1 so as to crystallize the semiconductor layer 2 (the step of crystallization). Specifically, Laser Annealing Treatment (step of crystallization) is carried out with respect to the semiconductor layer 2 on the surface of which the thermal diffusion layer 1 is formed.

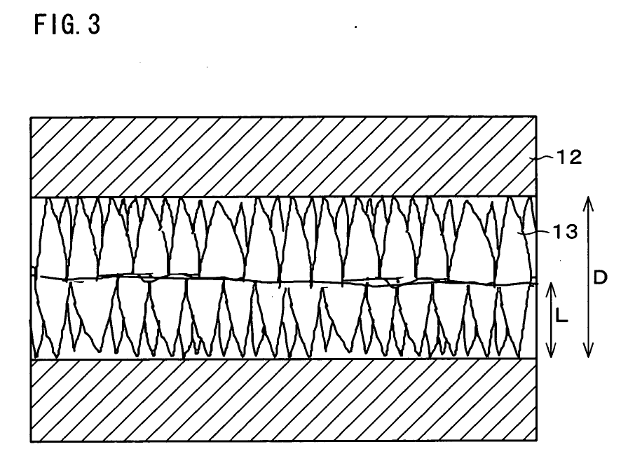

In reference to FIG. 2, the following explains an arrangement of a crystallization apparatus used for Laser Annealing Treatment. FIG. 2 is a plan view showing a schematic arrangement of the crystallization apparatus in accordance with the present embodiment. As shown in FIG. 2, the crystallization apparatus includes a laser light source 5, a photo mask 11 on which an irradiation pattern is formed, an objective lens 9, and a stage 10. According to need, the crystallization apparatus may further include a group of optical devices 6, such as a homogenizer, an expander, or the like, and a field lens 8.

Note that any crystallization apparatus may be used as long as the crystallization apparatus can irradiate light having a predetermined irradiance onto a predetermined position of the semiconductor device in a predetermined pattern, and the crystallization apparatus is not limited to the above arrangement.

The stage 10 is provided for mounting the semiconductor device in which the semiconductor layer 2 is not crystallized. The stage 10 is arranged so as to move the semiconductor device in a direction of the surface on which the semiconductor device is mounted.

It is more preferable that the laser light source (crystallization means) 5 can carry out pulse irradiation. For example, it is possible to use an excimer laser as the laser light source 5. It is preferable to use the excimer laser as the laser light source 5. This is because a wavelength of the laser light emitted from the excimer laser is in an ultraviolet region and it is so easy for the semiconductor layer 2 to absorb the laser light. In addition, a pulse width of the excimer laser is from 10 nanoseconds to several tens of nanoseconds. This allows the semiconductor layer 2 to be molten almost instantly. Note that the semiconductor layer 2 which has been molten by the laser light source 5 is quickly cooled down. In the process of cooling down, the semiconductor layer 2 is crystallized.

Moreover, it is possible to use a solid-state laser as the laser light source 5. According to the solid-state laser, a nonlinear optical crystal, such as Nd-YAG, is irradiated by a flash lamp or a semiconductor device laser so as to be excited. This allows the nonlinear optical crystal to carry out a laser oscillation. The solid-state laser does not require halogen which is required in the excimer laser. As such, the solid-state laser has an advantage of easy maintenance. Moreover, instead of the flash lamp, the semiconductor device laser may be used for excitation. In this case, it is possible for the semiconductor laser to carry out an oscillation with high efficiency. This is because the semiconductor device laser has a good oscillation and an oscillation wavelength of the semiconductor device laser is made fallen within an absorption band of the nonlinear optical crystal of the solid-state laser. On this account, it becomes possible to drastically reduce electric power consumption and the size of the solid-state laser using the semiconductor device laser, as compared with the excimer laser or the solid-state laser using the flash lamp.

Moreover, according to the solid-state laser, since the nonlinear optical crystal is excited, it becomes possible to obtain the laser light having a wavelength of around 1.06 μm. However, in the case of irradiating the laser light having the wavelength of substantially 1.06 μm onto the semiconductor layer 2, it is hard for the laser light to be absorbed by the amorphous silicon constituting the semiconductor layer 2. This is because the amorphous silicon has low absorption coefficient. On this account, it is hard for the semiconductor layer 2 to be molten. In view of the circumstances, it is desirable that the laser light be converted into visible light by the nonlinear optical crystal.

It is possible to use, for example, Nd-YAG, Nd-VO4, or the like as the nonlinear optical crystal. After passing through such nonlinear optical crystal, the laser light having the wavelength of 1.06 μm is converted into the visible light having a second harmonic wavelength of around 532 nm. The absorption coefficient of the amorphous silicon becomes high for the wavelength of around 532 nm or less. As a result, it becomes possible for the semiconductor layer 2 to be molten by the irradiation of the laser light. That is, in order to crystallize the semiconductor layer 2 which is amorphous (not crystallized), it is preferable that the laser light source 5 of the crystallization means emit the laser light having a wavelength of 550 nm or less. Especially, it is preferable that the laser light source 5 emit the laser light whose wavelength is 550 nm or less and is in a visible light region. Note that details concerning the wavelength of the laser light emitted from the laser light source 5 will be described later.

A beam (laser light) emitted from the laser light source 5 is converted by an expander into a beam having an appropriate beam size. Then, the irradiance in a cross section of the beam is uniformized by a homogenizer so that the photo mask 11 is irradiated by the beam. Here, the beam expander is an optical system having a telescopic system or a reduction system, and determines a size of an irradiated region on the photo mask 11. The homogenizer is constituted by a lens array or a cylindrical lens array. The homogenizer divides and recombines the beam so as to uniformize the irradiance of the beam within the irradiated region on the mask.

The photo mask 11 has a light shielding portion and an aperture portion on a mask substrate. The light emitted from the laser light source 5 is directed to and passes through the aperture portion. The mask substrate is made of a material, such as quartz, glass, or the like. Moreover, the light shielding portion is, for example, (i) a metal thin film, such as chromium, nickel, aluminum, or the like, (ii) a reflection film of a dielectric multilayer film, or (iii) an absorption film of the dielectric multilayer film.

The aperture portion formed on the photo mask 11 has a shape of slit having a width ranging from 1 μm to 100 μm, preferably, from 3 μm to 50 μm. It is preferable to form one or a plurality of the aperture portions. However, the shape of the photo mask 11 is not limited to a specific one.

The objective lens 9 forms on the surface of the semiconductor device an image formed by irradiating the laser light which passed through the homogenizer onto the aperture portion of the photo mask 11. That is, the image of the aperture portion is formed on the semiconductor device. Specifically, the laser light emitted from the laser light source 5 is irradiated onto a portion of the semiconductor layer 2 of the semiconductor device from above the thermal diffusion layer 1, whereas the laser light is not irradiated onto other portions. In this case, it is preferable that the laser light is irradiated only onto a region of the semiconductor layer 2 where the thermal diffusion layer 1 is provided. This can be achieved by (i) forming the thermal diffusion layer 1 on the entire glass substrate 4, and (ii) forming the image of the aperture portion on the thermal diffusion layer 1. Alternatively, that may be achieved by (i) forming the thermal diffusion layer 1 on a portion of the glass substrate 4, and (ii) forming the image of the aperture portion on a portion of the thermal diffusion layer 1.

In this case, it is more preferable that an optical magnification of the image to be formed on the semiconductor device be from 1/1 to 1/10. That is, it is more preferable that the image be so formed as to be 1/1 to 1/10 of the original. A resolution of the objective lens 9 is so determined that the image of the aperture portion can be resolved as the image formed on the semiconductor device in the case of forming on the semiconductor device the image of the aperture portion provided on the photo mask 11. That is, the resolution is usually so determined that the image formed on the semiconductor device, that is, a width of the slit can be resolved. Specifically, the resolution is expressed by substantially λ/NA, where NA indicates a numerical aperture of the objective lens 9 and λ indicates the wavelength to be used. Therefore, the width of the aperture portion is so determined that the aperture portion becomes substantially the value (λ/NA), or the numerical aperture of the objective lens is so determined that the resolution is equal to or less than the width of the aperture portion.

When the image of the aperture portion is formed by the objective lens 9 on the semiconductor layer 2 of the semiconductor device, that is, when the laser light from the laser light source 5 is irradiated onto the semiconductor layer 2, a portion of the semiconductor layer 2 where the laser light is irradiated absorbs the energy of the laser light so as to be molten. After finishing the irradiation (pulse irradiation) of the laser light, the temperature of the molten portion of the semiconductor layer 2 becomes the melt point or lower. This causes the molten portion of the semiconductor layer 2 to quickly cool down so as to be crystallized. In the molten portion of the semiconductor layer 2 to be crystallized, as shown in FIG. 3, a crystal 13 grows in a width direction D of the aperture portion, that is, in a width direction of the irradiated laser light. Then, the crystal 13 becomes a columnar crystal. Note that FIG. 3 is a front view showing a state of crystallization of the semiconductor layer 2. Moreover, as shown in FIG. 3, a portion 12 other than a portion on which the image of the aperture portion is formed, that is, a portion onto which the laser light is not irradiated is not molten, and the portion 12 remains in an amorphous state.

The crystallization of the semiconductor layer 2 (Laser Annealing Treatment with respect to the semiconductor layer 2) is carried out by using the crystallization apparatus arranged as above. Specifically, as described above, the laser light source 5 emits the laser light towards the semiconductor layer 2 from above the thermal diffusion layer 1. In this way, the laser light which passed through the thermal diffusion layer 1 is irradiated onto the semiconductor layer 2. Then, in the semiconductor layer 2, the portion irradiated by the laser light is molten. When the irradiation of the laser light is stopped, the molten portion of the semiconductor layer 2 cools down, and the molten portion of the semiconductor layer 2 is crystallized. The following explains the crystallization of the semiconductor layer 2 in detail.

In a conventional semiconductor device, that is, in a semiconductor device in which a diffusion preventing layer is provided between a substrate and a semiconductor layer, when the molten semiconductor layer is crystallized, a growth length L of the crystal is about 1 μm to 1.5 μm. Specifically, when the width D of the aperture portion whose image is formed on the substrate (width of the laser light to be irradiated onto the semiconductor device) is 5 μm, the crystal starts growing from an edge portion of the laser light through steps of melting and crystallization. However, the micro crystal or the amorphous state remains in a remaining portion of 2 μm to 3 μm at a center of the laser light. Thus, it is impossible to crystallize the entire portion of the aperture portion. The following explains why it is impossible.

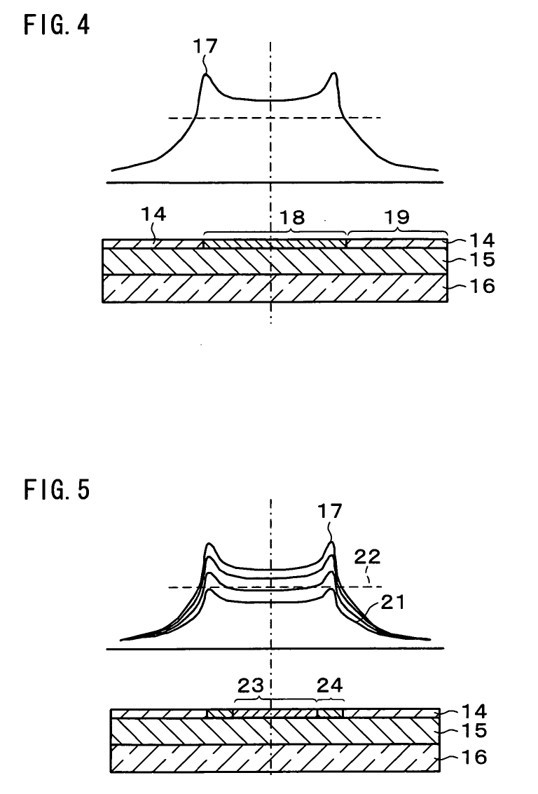

FIG. 4 is a graph showing a temperature distribution of an amorphous silicon film 14 on a diffusion preventing layer 15 which is formed on a glass substrate 16 in a conventional arrangement. Such an amorphous silicon film 14 is in a state in which it is cooled down and is now in the process of crystallization after irradiating the laser light onto the film 14 so that the film 14 is molten. In the arrangement shown in FIG. 4, no thermal diffusion layer is provided.

When the laser light is irradiated onto the amorphous silicon film 14 so that it is molten, (i) at the center of a region where the laser light is irradiated, there is a molten region 18 in which the amorphous silicon film 14 is molten, and (ii) around the molten region 18, there is a crystallized region 19 which has already been cooled down and has already been crystallized. Note that a region 17 in the vicinity of the boundary between the molten region 18 and the crystallized region 19, that is, a region 17 which is in the process of crystallization has a high temperature. This is because the molten amorphous silicon film 14 diffuses latent heat in the process of crystallization.

FIG. 5 is a graph showing a change in a temperature distribution of the amorphous silicon film 14 in a conventional arrangement, when the amorphous silicon film 14 decreases in temperature. A temperature level 22 shown in FIG. 5 indicates the freezing point of the amorphous silicon film (silicon) 14. When the temperature of the molten amorphous silicon film 14 is lower than the temperature level 22, the silicon constituting the amorphous silicon film 14 is crystallized (solidified).

In the above conventional arrangement, as the silicon is cooled down and decreases in temperature, the crystallization proceeds from an outer edge portion 21 towards the central portion of the molten region. While the crystallization proceeds from the outer edge portion 21, the central portion of the molten region decreases in temperature. This allows the crystallization of the central portion to proceed. Note that there is the region 17 which is in the process of crystallization between the outer edge portion 21 and the central portion. The temperature of the region 17 is higher than the temperature level 22. Therefore, before the crystallization proceeds from the outer edge portion 21 to the central portion, the temperature of the central portion becomes lower than the temperature level 22 so that the crystallization proceeds. This causes a crystal grain 23 which is the micro crystal or amorphous to be generated at the center portion. On this account, the growth of a crystal 24 crystallized in the process of the crystallization from the outer edge portion 21 to the central portion is hindered by the crystal grain 23 generated at the central portion. Thus, in the conventional arrangement, the crystal 24 may not grow up to the central portion.

According to the arrangement of the semiconductor device of the present embodiment, that is, according to an arrangement in which the diffusion preventing layer 3, the semiconductor layer 2, and the thermal diffusion layer 1 are stacked in this order on the glass substrate 4 (arrangement in which the thermal diffusion layer 1 is provided on the surface of the semiconductor layer 2) as shown in FIG. 1, the growth length L of the crystal can be increased twice to three times, as compared with the conventional case. That is, when each irradiation is carried out to the semiconductor layer 2 so that the layer 2 is molten and crystallized, it is possible that the growth length of the crystal falls within a range from 2 μm to 4 μm or more. Therefore, even in cases where the width D (width of the laser light to be irradiated onto the semiconductor device) of the image of the aperture portion is, for example, twice to three times wider than the conventional arrangement or much wider, it is possible to prevent the central portion from becoming the micro crystal or amorphous, or it is possible to reduce a width of the micro crystal or the amorphous at the central portion as compared with the conventional arrangement. The following explains the reasons thereof.

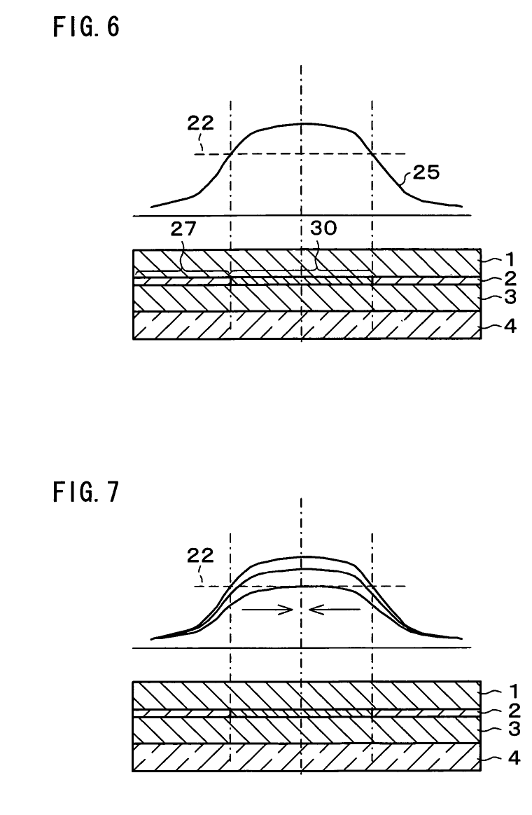

In the present embodiment, the laser light is applied to a non-crystallized semiconductor device which is so arranged that the diffusion preventing layer 3, the semiconductor layer (amorphous silicon layer) 2, and the thermal diffusion layer 1 are stacked in this order on the substrate 4. Therefore, as shown in FIG. 6, a boundary region between a crystallized region 27 and a molten region 30 is not so high in temperature. Moreover, a temperature distribution 25 indicates that the temperature slowly decreases from the central portion towards the outer edge portion. The reason for this is as follows: due to the thermal diffusion layer 1 provided on the surface of the semiconductor layer 2, the heat is liable to flow in a lateral direction (in an in-plane direction of the substrate) through the thermal diffusion layer 1, so that the boundary region quickly decreases in temperature. That is, by providing the thermal diffusion layer 1 on the surface of the semiconductor layer 2, it becomes possible to facilitate the flow of the heat in the lateral direction. As a result, it becomes possible to uniformize the temperature distribution, which conventionally has projected portions due to diffusion of the latent heat. Note that, FIG. 6 is a graph showing the temperature distribution of a region in the vicinity of the molten region, in the case in which the non-crystallized semiconductor device of the present embodiment is irradiated with the laser light.

On this account, when the entire molten region decreases in temperature as shown in FIG. 7, such a phenomenon that the crystallization occurs not only at the outer edge portion but also at the central portion does not occur. Therefore, the crystal grows smoothly from the outer edge portion towards the central portion. As a result, it is possible to generate a longer crystal than before from the outer edge portion to the central portion. Note that, FIG. 7 is a graph showing a change in a temperature distribution of the semiconductor layer 2 in an arrangement of the present embodiment, the change being caused due to a decrease in temperature of the semiconductor layer 2.

In the present embodiment, after crystallizing a portion on which the image of the aperture portion is formed, that is, after crystallizing a portion of the semiconductor device, the portion being irradiated with the laser light, the laser light is so moved as to be applied to the semiconductor device in such a manner that a part of the laser light overlaps with a portion which is not yet crystallized or a portion which has already been crystallized. As a result, the crystal of the semiconductor layer 2 on the substrate 4 can be increased in length. By repeating such irradiation, it becomes possible to crystallize a portion of or entirety of the semiconductor layer 2 formed on the substrate 4. Specifically, the laser light is further applied to a portion including the crystallized portion, that is, the laser light is applied to the semiconductor device so that the laser light overlaps with a part of the portion which has already been crystallized. In this way, it becomes possible to grow, as a seed crystal, the portion which has already been crystallized. Specifically, if an overlapping area of the laser light in a width direction is substantially half as much as the growth length L of the crystal, it is possible to further crystallize the crystal which has already been crystallized, in a continuous fashion. As a result, it becomes possible to generate the crystal which is long in an in-plane direction of the glass substrate 4 and in the width direction of the aperture portion.

Therefore, according to the method of manufacturing the crystallized semiconductor in accordance with the present embodiment, the crystallized region formed by a one-time pulse irradiation has an area twice as large as the conventional arrangement. As a result, it is possible to reduce in half a time necessary for crystallizing the semiconductor layer 2, so that an inexpensive semiconductor device is realized.

Moreover, by crystallizing the semiconductor layer 2 of the non-crystallized semiconductor device in accordance with the present embodiment, the crystallization can be carried out in a shorter period of time than the conventional arrangement. Moreover, by irradiating the semiconductor layer 2 with the laser light so that the laser light is applied to a part of the crystal which has already been formed, it becomes possible to further increase the growth length of the crystal.

For example, in the case of a transistor arranged such that carriers flow in a direction in which the crystal grows (in the width direction of the aperture portion), the carriers are not so scattered by grain boundaries of the crystals, and it becomes possible to obtain a transistor having quite high mobility.

Note that, in the present embodiment, one route for the heat to be diffused in a vertical direction from the thermal diffusion layer 1 is a route for the heat to be diffused upward (that is, to the air) through the thermal diffusion layer 1. However, because the air is gas and the thermal conductivity of the air is much lower than that of the glass layer 4 which is solid, it is possible to ignore the heat to be diffused into the air.

Moreover, as described above, as a material for forming the thermal diffusion layer 1 provided on the surface of the semiconductor layer 2, nitride, such as aluminum nitride, silicon nitride, or the like, can be used preferably. This is because many of such nitride have high thermal conductivity and high thermal resistance. In addition, many of such nitride are almost transparent at a wavelength of the laser light used for melting. Moreover, as a material of the thermal diffusion layer 1, it is possible to use many of the materials (for example, aluminum oxide) each of which has high thermal conductivity and high thermal resistance and is almost transparent at the wavelength of the laser light used for melting.

Among the materials capable of constituting the thermal diffusion layer 1, for example, each of aluminum nitride, silicon nitride, and aluminum oxide has the thermal conductivity higher than that of the glass substrate 4 for five times (to ten times) or more. According to an experiment, the growth length of the crystal is increased by using aluminum nitride, silicon nitride, or aluminum oxide as the material for the thermal diffusion layer 1. On the basis of this, it is more preferable that the thermal diffusion layer 1 be formed by a material having higher thermal conductivity than that of the glass substrate 4. It is further preferable that the thermal diffusion layer 1 be formed by a material having thermal conductivity not less than five times higher than that of the glass substrate 4. In this way, it becomes possible to obtain an effect of accelerating the growth of the crystal.

In addition, in a certain combination of the material constituting the thermal diffusion layer 1 and the type of the laser light source 5, the thermal diffusion layer 1 may considerably absorb the laser light applied to the semiconductor device. For example, in the case of using as the laser light source 5 the excimer laser having a wavelength in the ultraviolet region, the laser light emitted from the laser light source 5 may be absorbed in some degree by the thermal diffusion layer 1. In this case, the laser light having the wavelength in the ultraviolet region is absorbed by the thermal diffusion layer 1 provided on the surface of the semiconductor layer 2, so that the heat may not be given adequately to the semiconductor layer 2 which positions under the thermal diffusion layer 1. Moreover, in the case in which a large amount of light is absorbed by the thermal diffusion layer 1 and heat is generated, the thermal diffusion layer 1 increases in temperature. As a result, the thermal diffusion layer 1 may be damaged.

Therefore, it is preferable that the thermal diffusion layer 1 have an optical transmittance lower than an absorptivity of the semiconductor layer 2 provided under the thermal diffusion layer 1. That is, it is more preferable that an optical absorptivity of the thermal diffusion layer 1 with respect to the laser light emitted from the laser light source 5 be lower than that of the semiconductor layer 2. The method of lowering the optical absorptivity of the thermal diffusion layer 1 than that of the semiconductor layer 2 is, for example, (i) to change the wavelength of the laser light emitted from the laser light source 5, (ii) to use the thermal diffusion layer having lower optical absorptivity than that of the semiconductor layer, (iii) or another type of method.

For example, in the case in which the wavelength of the laser light emitted from the laser light source 5 is in the ultraviolet region, the thermal diffusion layer 1 may absorb much of the energy of the laser light, in a case where a certain type of the material constituting the thermal diffusion layer 1 is adopted.

On this account, it is preferable to change the wavelength of the laser light according to the type of the material constituting the thermal diffusion layer 1. For example, instead of the laser light having the wavelength in the ultraviolet region, the laser light having the wavelength in the visible light region may be used. By using the laser light source 5 for emitting the light having the wavelength at which the transmittance of the thermal diffusion layer 1 is high (the absorptivity of the thermal diffusion layer 1 is low) and at which the absorptivity of the semiconductor layer 2 is high, much of the laser light passes through the thermal diffusion layer 1 and then is absorbed by the semiconductor layer 2. As a result, it becomes possible to give enough heat to the semiconductor layer 2. Note that, in the case of using amorphous silicon or silicon as the semiconductor layer 2, it is preferable to use the laser light having the wavelength of shorter than 550 nm. This is because, in the case in which the material constituting the semiconductor layer 2 is silicon (including amorphous silicon), the silicon does not adequately absorb the laser light having the wavelength of longer than 550 nm. Therefore, in the case in which the material constituting the semiconductor layer 2 contains silicon, it is preferable to use the laser light having the wavelength of 550 nm or less.

Moreover, it is more preferable that the lower limit of the wavelength of the laser light applied to the semiconductor layer 2 be 350 nm or longer. In the case of the laser light having the wavelength of less than 350 nm, many of the materials (including materials which are transparent in the visible zone) each capable of constituting the thermal diffusion layer 1 absorb the laser light greatly. Therefore, in this case, it is possible to select from only a limited range of materials, such as silicon dioxide, calcium fluoride, or the like. However, in the case of the laser light having the wavelength of 350 nm or longer in the visible zone, it is possible to select a material having high transmittance, such as silicon nitride, aluminum nitride, aluminum oxide, or the like. Therefore, it is more preferable that a wavelength region of the laser light applied to the semiconductor layer 2 be in the range from 350 nm to 550 nm.

Therefore, in the case of using the visible light in the above range in order to melt the silicon on which the thermal diffusion layer 1 is provided, the absorption by the thermal diffusion layer 1 can be easily suppressed while melting the silicon efficiently. Therefore, this is especially preferable.

The light source (laser light source 5) for emitting the laser light having the wavelength region in the above range is, for example, the solid-state laser. Using the solid-state laser is preferable because the solid-state laser easily emits the laser light having the wavelength in the visible light region. Especially, using the second harmonic wave of the solid-state laser, such as Nd-YAG, is preferable because it is possible to obtain an oscillation wavelength of 532 nm.

Especially, by using the solid-state laser, it becomes possible to produce a compact and lightweight processor. Moreover, the processor does not require gas for its maintenance, so that it is possible to lower the maintenance cost. On this account, it is possible to reduce the maintenance cost of the manufacturing device. Moreover, because the cost of the processor and the maintenance cost are low in the case of using the processor, it is possible to realize the manufacturing method which can drastically lower the manufacturing cost as compared to the conventional arrangement.

Further, in the method of manufacturing the crystallized semiconductor device of the present embodiment, in the case of carrying out the crystallization in such a manner that the laser light is applied to the semiconductor layer 2 on the surface of which the thermal diffusion layer 1 is provided, the thermal diffusion layer 1 may be eliminated after the crystallization, and then the following steps may be carried out thereafter. By eliminating the thermal diffusion layer 1, it becomes easy to carry out the following steps, such as fabrication of a gate portion and electrode wiring, formation of a semiconductor device (doping), etc. After eliminating the thermal diffusion layer 1 formed on the surface of the semiconductor layer 2, the semiconductor device is made up of the semiconductor layer 2, the diffusion preventing layer 3, and the glass substrate 4. Here, because this arrangement is the same as that of a conventional device, it is possible to use a conventional process steps as they are. Moreover, it is possible to use conventional silicon dioxide for forming the diffusion preventing layer 3. Therefore, it is also possible to conveniently use a conventional step as it is. Especially, the diffusion preventing layer 3 has an important function of preventing the impurities from diffusing from the glass substrate 4. It is extremely convenient to use a material which is conventionally used for the diffusion preventing layer 3, because it becomes unnecessary to reconsider the steps. That is, one method of manufacturing the semiconductor device of the present embodiment may be realized by adding the following two steps to a conventional method of manufacturing the semiconductor device: (i) the step of providing the thermal diffusion layer being inserted between the step of providing the semiconductor layer 2 and the step of Laser Annealing Treatment in the conventional method, and (ii) the step of eliminating the thermal diffusion layer being inserted between the step of Laser Annealing Treatment and the following steps in the conventional method. Thus, the present method has fewer changes with respect to the conventional method, so that it is easy to shift from the conventional method to the present method. Note that, as a method of eliminating the thermal diffusion layer 1, it is possible to use, for example, so-called Dry Etching. According to Dry Etching, (i) first, oxygen and inactive gas (He, Ne, Ar, Kr, etc) are changed into plasma, (ii) then, these ions are caused to collide with the thermal diffusion layer 1 provided on the glass substrate 4, and (iii) finally, the energy of collision eliminates the thermal diffusion layer 1.

Moreover, in the present embodiment, the thermal diffusion layer 1 having high thermal conductivity is provided on the semiconductor layer 2. Therefore, it is possible to extend the growth length of the crystal. However, because a large amount of heat is transferred to the glass substrate 4 due to high thermal conductivity of the thermal diffusion layer 1, it may be necessary to slightly increase an amount of energy per irradiated area of the laser light necessary for Laser Annealing. That is, if the amount of energy of the laser light generated by one-time pulse irradiation is the same as the conventional arrangement, in order to increase the amount of energy per irradiated area of the laser light, it is more preferable to use a method of, for example, reducing a beam size converted by the expander or the like, that is, reducing the area (irradiated area) of the laser light applied to the semiconductor device.

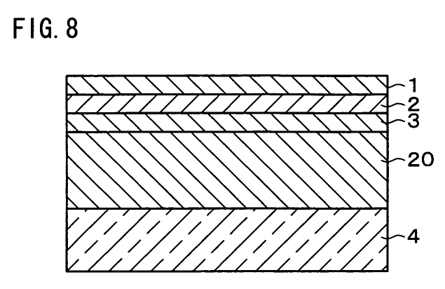

Moreover, in addition to the above method, it is preferable that the method of manufacturing the crystallized semiconductor of the present embodiment include the step of forming a low thermal conductivity layer which is provided between the glass substrate 4 and the semiconductor layer 2 and has lower thermal conductivity than that of the substrate. Specifically, in order to manufacture the crystallized semiconductor device, it is preferable to use the non-crystallized semiconductor device in which a low thermal conductivity layer 20 is formed between the glass substrate 4 and the semiconductor layer 2 as shown in FIG. 8. More specifically, as shown in FIG. 8, the low thermal conductivity layer 20 made of a material having lower thermal conductivity than that of the glass substrate 4 is provided under the diffusion preventing layer 3 provided under the semiconductor layer 2. This arrangement makes it possible to prevent heat loss. As the low thermal conductivity layer 20, it is possible to use porous silicon dioxide, an organic material film, or the like. By providing the low thermal conductivity layer 20, it becomes possible to prevent heat from diffusing to the glass substrate 4. On this account, it becomes possible to prevent the heat loss. Moreover, due to an effect of the thermal diffusion layer 1, it is possible to prevent uneven thermal distribution, and also possible to facilitate the growth satisfactorily. Especially, by providing the low thermal conductivity layer 20, it is possible to prevent a steep change in temperature of the molten semiconductor layer 2, and also possible to further increase the size of the crystal to be generated. Thus, the heat distributed unevenly can be diffused in the lateral direction (in the direction of the substrate). Therefore, the temperature distribution of the molten semiconductor layer 2 can be uniformized further.

Moreover, the non-crystallized semiconductor device of the present embodiment may be so arranged that the thermal diffusion layer 1 having higher thermal conductivity than that of the glass substrate 4 is formed on the surface of the semiconductor layer 2 which is provided on the glass substrate 4 and is in an amorphous state or a micro crystal state.

According to the above arrangement, the thermal diffusion layer 1 is formed on the surface of the semiconductor layer 1. The thermal diffusion layer 1 has higher thermal conductivity than that of the glass substrate 4. Therefore, when crystallizing the semiconductor layer 2, the molten semiconductor layer 2 does not decrease in temperature quickly. That is, because the thermal diffusion layer 1 is formed on the surface of the semiconductor layer 2, it is possible to increase, the size (length) of the crystal generated in the crystallization of the semiconductor layer 2, as compared to the conventional arrangement. Moreover, in addition to the above arrangement, the non-crystallized semiconductor device of the present embodiment may be so arranged that another thermal diffusion layer is formed between the semiconductor layer 1 and the glass substrate 4. By providing the thermal diffusion layer 1 on the surface of the semiconductor layer 2, it becomes possible to further improve effects of (i) facilitating the flow of the heat in the lateral direction, and (ii) uniformizing the temperature distribution which conventionally has projected portions due to the diffusion of the latent heat.

Moreover, the method of manufacturing the crystallized semiconductor device of the present embodiment includes the steps of (i) providing the semiconductor layer 2 on the glass substrate 4 and (ii) irradiating the semiconductor layer 2 with the laser light so as to crystallize the semiconductor layer 2. The method may further include the step of forming on the semiconductor layer 2 the thermal diffusion layer 1 having higher thermal conductivity than that of the glass substrate 4, and in the step of crystallization (step (ii)), the application of the laser light may be carried out from above the thermal diffusion layer 1.

Moreover, the crystallization apparatus of the present embodiment includes the crystallization means which applies the laser light to the glass substrate 4 on which the semiconductor layer 2 is provided and the thermal diffusion layer 1 having high thermal conductivity is provided on the semiconductor layer 2, so as to crystallize the semiconductor layer 2. The crystallization means may be so arranged as to irradiate the semiconductor layer 2 with the laser light from above the thermal diffusion layer 1.

Note that, the foregoing explains an arrangement in which the thermal diffusion layer 1 is formed on the surface of the semiconductor layer 2. However, for example, another layer can be provided between the thermal diffusion layer 1 and the semiconductor layer 2.

Moreover, in the method of manufacturing the crystallized semiconductor device of the present invention, it is preferable to carry out the step of eliminating the thermal diffusion layer after the step of crystallization.

According to the above arrangement, by eliminating the thermal diffusion layer formed on the surface of the semiconductor layer, it is possible to obtain the semiconductor device having the arrangement similar to the conventional one, and also possible to obtain the crystallized semiconductor device having a larger size of the crystal grain as compared to the conventional arrangement. Therefore, for example, by eliminating the thermal diffusion layer, it becomes possible to use the steps similar to those in the conventional arrangement, even in the case of manufacturing various devices by using the crystallized semiconductor device. Therefore, it is possible to restrain an equipment investment and reduce the manufacturing costs.

In the method of manufacturing the crystallized semiconductor device of the present invention, it is preferable that the thermal diffusion layer have lower optical absorptivity with respect to the laser light than that of the semiconductor layer.

According to the above arrangement, by using the thermal diffusion layer having lower optical absorptivity with respect to the laser light than that of the semiconductor layer, most energy of the laser light can be given to the semiconductor layer. That is, it is possible to suitably melt the semiconductor layer. As a result, it is possible to improve the efficiency of the step of crystallization, and also possible to reduce the manufacturing costs by reducing the manufacturing time.

In the method of manufacturing the crystallized semiconductor device of the present invention, it is preferable that the laser light having the wavelength of 550 nm or less is used in the step of crystallization.

According to the above arrangement, the laser light having the wavelength of 550 nm or less is applied to the semiconductor layer in the step of crystallization. More preferably, the laser light having the wavelength of 350 nm to 550 nm is applied to the semiconductor layer. By using the laser light having the above wavelength, it is possible to reduce the absorption of the laser light in the thermal diffusion layer and also possible to absorb a large amount of the laser light in the semiconductor layer. Therefore, it becomes possible to improve the efficiency of the crystallization of the semiconductor layer. As a result, it becomes possible to reduce the manufacturing costs by reducing the time for manufacturing the crystallized semiconductor device.

It is more preferable that the method of manufacturing the crystallized semiconductor device of the present invention include the step of forming the low thermal conductivity layer which is formed between the substrate and the semiconductor layer and has lower thermal conductivity than that of the substrate.

According to the above arrangement, the low thermal conductivity layer is formed between the substrate and the semiconductor layer. With this, it is possible to prevent heat from flowing to the substrate, the heat being generated by the laser light applied to the semiconductor layer. That is, it is possible to keep the heat in the molten semiconductor layer. Therefore, it is possible to slow down the speed of decrease in temperature of the semiconductor layer as compared to the conventional arrangement. On this account, it becomes possible to manufacture the crystallized semiconductor device having the semiconductor layer in which the size of the crystal grain is much lager than that of the conventional arrangement.

In the crystallization apparatus of the present invention, it is preferable that the laser light emitted from the crystallization means have the wavelength which is so determined that the thermal diffusion layer has lower optical absorptivity with respect to the laser light than that of the semiconductor layer.

According to the above arrangement, the laser light can be applied in such a way that (i) it is possible to reduce the absorption of the laser light in the thermal diffusion layer and (ii) also possible to absorb a large amount of the laser light in the semiconductor layer. As a result, it is possible to improve the efficiency of the crystallization, and also possible to reduce the manufacturing costs by reducing the time for crystallization.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

As above, according to the present invention, it is possible to manufacture the crystallized semiconductor device having the semiconductor layer in which the size of the crystal grain is larger than that of the conventional arrangement. Therefore, it is possible to improve a property of the crystallized semiconductor device, and also possible to manufacture the device at low costs.

1. A method of manufacturing a crystallized semiconductor device comprising the steps of:
(i) forming a semiconductor layer on a substrate;
(ii) irradiating the semiconductor layer with laser light so as to crystallize the semiconductor layer; and
(iii) forming a thermal diffusion layer on a surface of the semiconductor layer, the thermal diffusion layer having higher thermal conductivity than thermal conductivity of the substrate,
in the step (ii), the semiconductor layer being irradiated with the laser light from above the thermal diffusion layer.

2. The method as set forth in claim 1, further comprising the step of eliminating the thermal diffusion layer after the step (ii).

3. The method as set forth in claim 2, wherein the thermal diffusion layer has lower optical absorptivity with respect to the laser light than optical absorptivity of the semiconductor layer.

4. The method as set forth in claim 1, wherein the laser light having a wavelength of 550 nm or less is used in the step (ii).

5. The method as set forth in claim 4, wherein the laser light having the wavelength of 350 nm or more is used in the step (ii).

6. The method as set forth in claim 5, wherein the laser light is visible light.

7. The method as set forth in claim 1, further comprising the step of forming a low thermal conductivity layer which is formed between the substrate and the semiconductor layer and has lower thermal conductivity than the thermal conductivity of the substrate.

8. The method as set forth in claim 1, wherein an optical transmittance of the thermal diffusion layer with respect to the laser light is 70% or more.

9. The method as set forth in claim 1, wherein the thermal diffusion layer is made of silicon nitride, aluminum nitride, silicon oxide, or aluminum oxide.

10. A crystallized semiconductor device manufactured by the method as set forth in any one of claims 1 to 9.

11. A crystallization apparatus for crystallizing a semiconductor layer, the crystallization apparatus comprising a crystallization means for irradiating a semiconductor device with laser light so as to crystallize the semiconductor layer, the semiconductor device having a thermal diffusion layer on a surface of the semiconductor layer provided on a substrate, the thermal diffusion layer having higher thermal conductivity than thermal conductivity of the substrate,
the crystallization means having a laser light source capable of emitting the laser light having a wavelength of 550 nm or less.

12. The crystallization apparatus as set forth in claim 11, wherein the wavelength of the laser light emitted from the laser light source is so determined that the thermal diffusion layer has lower optical absorptivity with respect to the laser light than optical absorptivity of the semiconductor layer.

13. The crystallization apparatus as set forth in claim 11, wherein the laser light emitted from the laser light source has the wavelength of 350 nm or more.

14. The crystallization apparatus as set forth in claim 11, wherein the laser light source is an excimer laser.

15. The crystallization apparatus as set forth in claim 11, wherein the laser light source is a solid-state laser.
